(19) United States
(12) Patent Application Publication
(10) Pub. No.: US 2015/0041783 A1
(43) Pub. Date: Feb. 12, 2015

(54) ORGANIC ELECTROLUMINESCENCE ELEMENT

(71) Applicant: PANASONIC CORPORATION, Osaka (JP)

(72) Inventors: Nobuhiro Ide, Osaka (JP); Kazuyuki Yamae, Nara (JP); Shintaro Hayashi, Hyogo (JP); Yuko Suzuka, Osaka (JP); Yoshikazu Kuzuoka, Osaka (JP); Hitomichi Takano, Osaka (JP)

(21) Appl. No.: 14/375,458

(22) PCT Filed: Feb. 13, 2013
(86) PCT No.: PCT/JP2013/000782

§ 371 Date: Jul. 30, 2014

(30) Foreign Application Priority Data
Feb. 13, 2012 (JP) 2012-028165

(51) Int. Cl. H01L 51/52

(52) U.S. Cl. CPC H01L 51/5253; H01L 51/5262; H01L 51/5203
USPC 257/40

(57) ABSTRACT

The organic electroluminescence element in accordance with the present invention, includes: a substrate; a light-emitting stack on a face of the substrate; a covering substrate provided so as to face the face of the substrate; and a sealing bond surrounding the light-emitting stack and bonding the substrate and the covering substrate to enclose the light-emitting stack together with the covering substrate and the substrate. The sealing bond includes a bonding layer and a low moisture permeable layer, and the low moisture permeable layer is lower in moisture permeability and thicker than the bonding layer.

### TECHNICAL FIELD

The present invention relates to organic electroluminescence elements.

### BACKGROUND ART

Recently, organic electroluminescence elements (organic EL elements) have been applied in the applications of illumination panels or the like. Known has been an organic EL element in which a light-transmissive first electrode (anode), an organic layer composed of a plurality of layers including a light-emitting layer, and a second electrode (cathode) are stacked on a surface of a light-transmissive substrate in this order. In the organic EL element, light produced in the light-emitting layer by applying a voltage between the anode and the cathode is extracted outside through the light-transmissive electrode and substrate.

Generally, the light produced in the light-emitting layer may be absorbed by the substrate or lost by total reflection at layer interfaces, and this causes a decrease in an amount of light. Hence, an amount of the light emitted outside is less than a theoretical amount of the light produced in the light-emitting layer. Therefore, improvement of the light-outcoupling efficiency to achieve higher luminance is one of problems to be solved in the field of the organic electroluminescence elements. One of known solutions to improve the light-outcoupling efficiency is to provide a light-outcoupling layer between the first electrode and the light-transmissive substrate. Owing to the light-outcoupling layer in the organic EL element, it is possible to suppress total reflection at an interface between the substrate and the electrode and extract a more amount of light to the outside.

Since the organic layer of the organic EL element is likely to be degraded by moisture as described in Document 1 (JP 2005-108824 A), it is important for the organic EL element to prevent moisture intrusion into the element. Degradation of the organic layer causes insufficient light emission efficiency and a drop in reliability of the organic EL element. For protection of the organic layer from moisture, a stack including the organic layer is normally covered with a cover bonded to the light-transmissive substrate and isolated from the outside. When the light-transmissive substrate and the cover are of glass materials, since the glass materials are resistant to moisture penetration, moisture intrusion therethrough is less likely to occur. However, a bonding material to bond the light-transmissive substrate to the cover is often a resin. Since the resin is higher permeable to moisture than glass is, moisture intrusion through the resin may cause problems.

To suppress moisture intrusion through the bonding material, the bonding material may have a moisture-proof property. However, in the organic EL element including the light-outcoupling layer on the stack to improve the light-outcoupling efficiency, the thickness of the stack is increased by the thickness of the light-outcoupling layer, and therefore a distance between the light-transmissive substrate and the cover is increased. Hence, the thickness of the bonding material is increased. When the light-outcoupling layer is not provided, bonding with the moisture-proof resin may suppress moisture intrusion therethrough to an ignorable degree. However, when the thickness of the bonding material is increased with an increase in the distance between parts to be bonded, moisture intrusion through the bonding material is not ignorable.

### SUMMARY OF INVENTION

The present invention has been made in view of the above circumstances, and the object thereof is to provide an organic electroluminescence element which has superior light-outcoupling efficiency and yet can suppress moisture intrusion efficiently and thus is highly reliable and is less likely to deteriorate.

According to the first aspect of the present invention, there is provided an organic electroluminescence element including: substrate having a face in a thickness direction of the substrate; a light-emitting stack on the face of the substrate; a covering substrate provided so as to face the face of the substrate; and a sealing bond surrounding the light-emitting stack and bonding the substrate and the covering substrate to enclose the light-emitting stack together with the covering substrate and the substrate. The light-emitting stack includes: a first electrode on the face of the substrate; a second electrode provided so as to face an opposite face of the first electrode from the substrate; and an organic layer provided between the first electrode and the second electrode and configured to emit light when a voltage is applied between the first electrode and the second electrode. The sealing bond includes a bonding layer and a low moisture permeable layer, and the low moisture permeable layer is lower in moisture permeability and thicker than the bonding layer.

According to the second aspect of the present invention referring to the first aspect, there is provided an organic electroluminescence element in which the bonding layer and the low moisture permeable layer are arranged in the thickness direction.

According to the third aspect of the present invention referring to the first or second aspect, there is provided an organic electroluminescence element in which the substrate and the first electrode transmit the light emitted from the organic layer.

According to the fourth aspect of the present invention referring to the third aspect, there is provided an organic electroluminescence element in which: the light-emitting stack further includes a light-outcoupling layer; and the light-outcoupling layer is disposed between the first electrode and the substrate to suppress reflection of the light emitted from the organic layer between the substrate and the light-emitting stack.

According to the fifth aspect of the present invention referring to any one of the first to fourth aspects, there is provided an organic electroluminescence element in which the low moisture permeable layer is a metal-containing layer which contains metal.

According to the sixth aspect of the present invention referring to the fifth aspect, there is provided an organic electroluminescence element in which the low moisture permeable layer is electrically connected to either the first electrode or the second electrode.

According to the seventh aspect of the present invention referring to the fifth aspect, there is provided an organic electroluminescence element in which: the low moisture permeable layer further includes a first auxiliary electrode electrically connected to the first electrode and a second auxiliary electrode electrically connected to the second electrode; the sealing bond further includes a sealing insulator having electrically insulating properties; and the sealing insulator is provided between the first auxiliary electrode and the second auxiliary electrode to prevent physical contact between the first auxiliary electrode and the second auxiliary electrode.

According to the eighth aspect of the present invention referring to any one of the fifth to seventh aspects, there is provided an organic electroluminescence element in which the low moisture permeable layer is formed to electrically connect the light-emitting stack to external electrodes to apply a voltage across the light-emitting stack.

According to the ninth aspect of the present invention referring to any one of the first to fourth aspects, there is provided an organic electroluminescence element in which the low moisture permeable layer is an inorganic insulating layer made of an inorganic material and having electrically insulating properties.

According to the tenth aspect of the present invention referring to any one of the first to ninth aspects, there is provided an organic electroluminescence element in which the bonding layer includes a first bonding layer bonding the low moisture permeable layer to the covering substrate and a second bonding layer bonding the low moisture permeable layer to the substrate.

According to the eleventh aspect of the present invention referring to any one of the first to ninth aspects, there is provided an organic electroluminescence element in which: the low moisture permeable layer is provided on either one of the substrate and the covering substrate; and the bonding layer bonds the low moisture permeable layer to the other of the substrate and the covering substrate.

### BRIEF DESCRIPTION OF DRAWINGS

FIG. 1A is a plan view illustrating an example of an embodiment of the organic electroluminescence element;

FIG. 1B is a cross-sectional view along the line X-X′ in FIG. 1A;

FIG. 2 is a cross-sectional view illustrating the first modification of the embodiment of the organic electroluminescent element;

FIG. 3 is a cross-sectional view illustrating the second modification of the embodiment of the organic electroluminescent element;

FIG. 4 is a cross-sectional view illustrating the third modification of the embodiment of the organic electroluminescent element;

FIG. 5 is a plan view illustrating the fourth modification of the embodiment of the organic electroluminescent element;

FIG. 6A is a plan view illustrating the fifth modification of the embodiment of the organic electroluminescence element;

FIG. 6B is a cross-sectional view along the line X-X′ in FIG. 6A;

FIG. 7A is a plan view illustrating the sixth modification of the embodiment of the organic electroluminescence element; and

FIG. 7B is a cross-sectional view along the line X-X′ in FIG. 7A.

### DESCRIPTION OF EMBODIMENTS

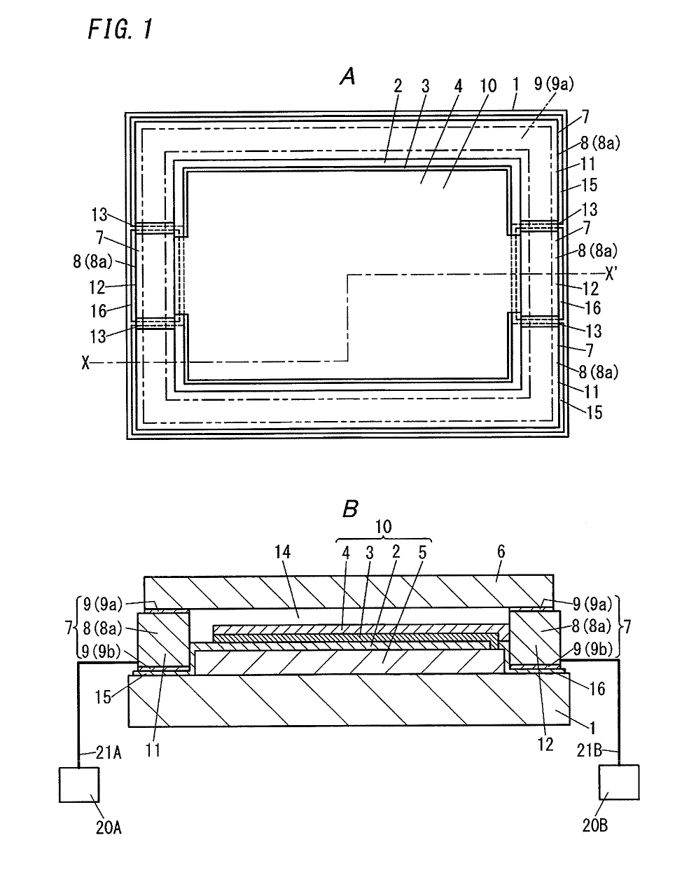

FIGS. 1A and 1B show an example of an embodiment of the organic electroluminescence element (organic EL element). The organic EL element includes a light-transmissive substrate (substrate) 1 and a light-emitting stack 10 on a face (upper face in FIG. 1B) of the light-transmissive substrate 1. The light-emitting stack 10 includes a light-outcoupling layer 5, a first electrode 2 with light-transmissive properties, an organic layer 3, and a second electrode 4 which are arranged in this order.

In short, as shown in FIG. 1B, the light-emitting stack 10 is on the face (upper face in FIG. 1B) of the substrate 1. The light-emitting stack 10 includes the first electrode 2 on the face of the substrate 1 and the second electrode 4 over an opposite face (upper face in FIG. 1B) of the first electrode 2 from the substrate 1 so as to face the opposite face. The light-emitting stack 10 further includes the organic layer 3 interposed between the first electrode 2 and the second electrode 4. The organic layer 3 emits light when a voltage is applied between the first electrode 2 and the second electrode 4. The first electrode 2, the organic layer 3, and the second electrode 4 are arranged in a thickness direction of the substrate 1 (up and down direction in FIG. 1B) in this order from the substrate 1.

The light-emitting stack 10 is enclosed by the light-transmissive substrate 1 and a covering substrate 6 facing each other and a sealing bond 7 which surrounds a periphery of the light-emitting stack 10 and bonds the covering substrate 6 and the light-transmissive substrate 1 to each other. In other words, the covering substrate 6, the substrate 1, and the sealing bond 7 enclose the light-emitting stack 10. Note that, in FIG. 1A, for concise illustration of configuration of the organic EL element, the covering substrate 6 is not illustrated, and a region where a first bonding layer 9a, which is a part of the sealing bond 7, is to be formed is indicated by two-dot chain lines.

The light-transmissive substrate (substrate) 1 is a transparent substrate with light-transmissive properties, and may be a glass substrate or the like. In the present embodiment, the substrate 1 transmits light emitted from the organic layer 3. When the light-transmissive substrate 1 is a glass substrate, glass is low permeable to moisture, and therefore it is possible to suppress moisture penetration into a sealed region. The sealed region is defined as a region enclosed by the substrate 1, the covering substrate 6, and the sealing bond 7. In the present embodiment of the organic EL element, the light-emitting stack 10 is on the surface of the light-transmissive substrate 1. A region where the light-emitting stack 10 is formed is a central region of the substrate 1 in a plan view (seen in a perpendicular direction to the surface of the substrate 1, namely, the thickness direction of the substrate 1; the perpendicular direction to a paper of FIG. 1A; the up and down direction in FIG. 1B). The sealing bond 7 is provided along the entire periphery of the light-emitting stack 10, and the light-emitting stack 10 is inside the sealed region.

In the present embodiment, the light-emitting stack 10 is a stack of the light-outcoupling layer 5, the first electrode 2, the organic layer 3, and the second electrode 4. The light-emitting stack 10 includes the light-outcoupling layer 5 constituting the closest layer of the light-emitting stack 10 to the light-transmissive substrate 1. That is, the light-emitting stack 10 includes the light-outcoupling layer 5, which is to be interposed between the substrate 1 and the first electrode 2. The light-outcoupling layer 5 is transmissive to light emitted from the organic layer 3, and suppresses reflection of the light between the light-emitting stack 10 and the substrate 1. In other words, the light-outcoupling layer 5 has light-transmissive properties and serves as a layer to extract a more amount of the light produced in the organic layer 3 to the outside of the sealed region through the first electrode 2. Note that the light-outcoupling layer 5 is an optional component. In other words, the light-emitting stack 10 does not necessarily include the light-outcoupling layer 5. In the present embodiment, owing to the light-outcoupling layer 5 of the light-emitting stack 10, the light produced in the organic layer 3 can be effectively extracted to the outside of the sealed region.

The light produced in the organic layer 3 reaches the substrate 1 directly or through reflection. When the difference in refractive index between the light-transmissive substrate 1 and the light-emitting stack 10 is large, the light may not extracted outward effectively due to total reflection. In this regard, when the light-emitting stack 10 includes the light-outcoupling layer 5 which is a layer below the first electrode 2 (namely, a layer at a light-outcoupling side) and has a refractive index closer to that of the first electrode 2, it is possible to reduce the difference in refractive index between the first electrode 2 and the light-outcoupling layer 5. Hence, it is possible to improve the light-outcoupling efficiency. The light-outcoupling layer 5 has the refractive index between those of the first electrode 2 and the light-transmissive substrate 1, and therefore suppresses total reflection of the light, which is emitted from the organic layer 3, between the light-emitting stack 10 and the substrate 1. Besides, the light-outcoupling layer 5 preferably has a function of scattering light as described below. When the light-outcoupling layer 5 has the function of scattering light, the light towards the light-transmissive substrate 1 is scattered by the light-outcoupling layer 5, and thus total reflection is suppressed. Hence, it is possible to extract a more amount of light to the outside.

The light-outcoupling layer 5 may be a plastic layer, for example. The plastic layer may be a molded product (sheet, film, or the like) formed by molding and curing a synthetic resin as a raw material of a plastic product and is used as a layer to be attached to the light-transmissive substrate 1. The plastic layer may be a layer made of a plastic material such as PET (polyethylene terephthalate) and PEN (polyethylene naphthalate). In order to form the light-outcoupling layer 5 of a plastic sheet, the light-outcoupling layer 5 may be formed by attaching a member for the light-outcoupling layer 5 on a surface of the light-transmissive substrate 1. Attaching may be conducted by thermocompression bonding or with an adhesive. In order to form the light-outcoupling layer 5 of a resin layer, the light-outcoupling layer 5 may be formed by applying a resin material onto the surface of the light-transmissive substrate 1. The light-outcoupling layer 5 with the function of scattering light may be formed by providing a light-scattering substance (e.g., particles and voids) in the plastic layer. In this regard, light is to be scattered through reflection on surfaces of particles or reflection and/or refraction due to a difference in refractive index of various components.

Between the light-transmissive substrate 1 and the light-outcoupling layer 5, a light-outcoupling structure may be provided for improving the light-outcoupling efficiency. Accordingly, the light-outcoupling efficiency can be more improved. The light-outcoupling structure may be formed by providing an uneven structure or providing a light-scattering layer containing the light-scattering substance, on the surface of the light-transmissive substrate 1. Furthermore, a light-outcoupling functional portion may be provided on a surface of the light-transmissive substrate 1 at the outside (opposite surface of the substrate 1 from the light-emitting stack 10; lower surface in FIG. 1B). The light-outcoupling structure and the light-outcoupling functional portion may be light-transmissive.

In the present embodiment, the light-emitting stack 10 is a stack where the first electrode 2, the organic layer 3, and the second electrode 4 are formed on the surface (upper face in FIG. 1B) of the light-outcoupling layer 5. Accordingly, the light-outcoupling layer 5 also serves as a substrate for forming the first electrode 2, the organic layer 3, and the second electrode 4.

Normally, the first electrode 2 serves as an anode, and the second electrode 4 serves as a cathode. Alternatively, the first electrode 2 may serve as a cathode, and the second electrode 4 may serve as an anode. In the present embodiment, the first electrode 2 is light-transmissive and serves as an electrode at the light-outcoupling side. In other words, in the present embodiment, the first electrode 2 is a light-transmissive electrode to transmit the light emitted from the organic layer 3. The second electrode 4 may be light-reflective. The second electrode 4 is an electrode to reflect the light emitted from the organic layer 3. In this case, the light from the organic layer 3 towards the second electrode 4 may be reflected at the second electrode 4 and then extracted through the substrate 1.

The second electrode 4 may be a light-transmissive electrode. That is, the second electrode 4 may be an electrode to transmit the light emitted from the organic layer 3. When the second electrode 4 is light-transmissive, the covering substrate 6 also transmits the light emitted from the organic layer 3. Accordingly, the structure of the organic EL element may be designed so that light is extracted through a back side (covering substrate 6 side) of the organic EL element. In this case, the substrate 1 and the first electrode 2 do not necessarily transmit the light emitted from the organic layer 3. In a case where the second electrode 4 is light-transmissive, when a light-reflective layer (a layer to reflect the light from the organic layer 3) is provided on the back side (upper face in FIG. 1B) of the second electrode 4, the light proceeding towards the second electrode 4 from the organic layer 3 may be reflected and extracted from the light-transmissive substrate 1. In this regard, the light-reflective layer may be scattering reflective or specular reflective.

The first electrode 2 and the second electrode 4 are made of electrically conductive materials with electrical conductivity. Each of the first electrode 2 and the second electrode 4 is in the form of a layer. In short, each of the first electrode 2 and the second electrode 4 is an electrically conductive layer with electrical conductivity. In the present embodiment, the first electrode 2 is a light-transmissive electrode, and is also a transparent electrically conductive layer which is transparent and electrically conductive.

The light-transmissive electrode may be formed of electrically conductive oxide (e.g., ITO, IZO, AZO, GZO, and SnO₂), electrically conductive material (e.g., a metallic nanowire, a metallic thin film, a carbon-based compound, an electrically conductive polymer, and the like), or a combination thereof. The light-transmissive electrode may be composed of an electrode layer made of the above-described electrically conductive oxide, electrically conductive material, or combination thereof, and metallic wires having higher electrically conductivity than that of the electrode layer on a surface of the electrode layer. In this case, the light-transmissive electrode having a smaller resistance (sheet resistance) may be provided. Note that the metallic wires are arranged in a stripe manner or in a grid manner so as not to block all of rays of light from the organic layer 3. Alternatively, the light-transmissive electrode may be a stack of the electrode layer made of the above-described electrically conductive oxide, and/or an electrically conductive material, and/or combinations thereof; and an electrically conductive thin film having higher electrical conductivity than that of the electrode layer. Also in this case, the light-transmissive electrode having a smaller resistance (sheet resistance) may be provided. Note that, in order not to entirely block the light from the organic layer 3, the electrically conductive thin film is so thin that optical absorption of the light in the electrically conductive thin film is small. The stack of the light-transmissive electrode may include a plurality of electrode layers and/or a plurality of electrically conductive thin films. For example, the stack may include two electrode layers and one electrically conductive thin film, and the electrically conductive thin film is interposed between the two electrode layers.

The organic layer 3 functions as a layer to cause light emission. The organic layer 3 includes a plurality of layers arbitrarily selected from a hole injection layer, a hole transport layer, a light-emitting layer, an electron transport layer, an electron injection layer, and an intermediate layer.

The covering substrate 6 is made of a substrate material which is low permeable to moisture. For example, the covering substrate 6 is a glass substrate, a metal substrate, or the like. The covering substrate 6 may have a recessed portion to accommodate the light-emitting stack 10, but may not have. In case of using the covering substrate 6 devoid of the recessed portion, it is possible to bond the covering substrate 6 to the substrate 1 with a flat face of the covering substrate 6 facing the substrate 1. Besides, a substrate with a plate shape may be used as the covering substrate 6 without any modification, and thus preparation of the organic EL element can be facilitated. In the organic EL element of the present embodiment, by bonding the covering substrate 6 and the substrate 1 to each other with the sealing bond 7 having low moisture permeability, it is possible to more suppress moisture penetration even when the recess portion for accommodating the light-emitting stack 10 is not formed.

The region (sealed region) covered with the covering substrate 6 contains a sealed space 14. In the sealed space 14, a desiccant may be provided. Accordingly, even if moisture enters the sealed space 14, the entering moisture may be absorbed by the desiccant. For example, the desiccant is provided in the sealed space 14 by pasting the desiccant on a face (lower face in FIG. 1B) of the covering substrate 6 close to the light-emitting stack 10. The sealed space 14 may be filled with filler. When the desiccant is provided in the sealed space 14, the thickness of a low moisture permeable layer 8 is preferably adjusted appropriately in view of possibility that the desiccant gets contact with the light-emitting stack 10 and gives damage to the light-emitting stack 10 unfortunately.

In the organic EL element, in order to cause light emission, the voltage is applied between the first electrode 2 and the second electrode 4 to recombine holes with electrons in the organic layer 3. To achieve this, electrode terminals electrically connected to the first electrode 2 and the second electrode 4, respectively are formed so as to extend to the outside of the sealed region. The electrode terminals are terminals for electrically connecting the first electrode 2 and the second electrode 4 to the external electrodes 20 individually. In the embodiment shown in FIG. 1, on a surface of each of the electrode extended portions (a first electrode extended portion 15 and a second electrode extended portion 16) extended from the first electrode 2 of the light-emitting stack 10, a metal-containing layer 8a (described below) as the low moisture permeable layer 8 is provided, and a stack of the electrode extended portion and the metal-containing layer 8a serves as the electrode terminal.

As the electrode extended portions, the first electrode extended portion(s) 15 electrically connected to the first electrode 2 and the second electrode extended portion(s) 16 electrically connected to the second electrode 4 are formed on a surface at a periphery of the light-transmissive substrate 1. The first electrode extended portion 15 and the second electrode extended portion 16 are not in physical contact with each other so as not to cause short circuiting in the organic EL element.

In the present embodiment, an electrically conductive layer for forming the first electrode 2 includes a portion extending toward the periphery of the light transmissive substrate 1 so as to overlap the region where the sealing bond 7 is to be formed, and this portion serves as the first electrode extended portion 15. In other words, with regard to the periphery on which the first electrode extended portion 15 is to be formed, the electrically conductive layer for forming the first electrode 2 extends to the outside of the surface of the light-outcoupling layer 5 opposite the covering substrate 6 so as to be on side faces of the light-outcoupling layer 5 (face close to the sealing bond 7) and on the surface of the light-transmissive substrate 1 close to the covering substrate 6. The first electrode extended portion 15 electrically connected to the first electrode 2 is extended to at least a border, between the substrate 1 and the sealing bond 7, of the region (sealed region) enclosed by the substrate 1, the sealing bond 7, and the covering substrate 6. By doing so, the electrode terminal can be formed outside the sealed region. In short, when the first electrode extended portion 15 is formed outside the sealed region, the first electrode extended portion 15 can function as the electrode terminal. In the present embodiment, the first electrode extended portion 15 is formed to extend to the outside of the sealed region.

In the present embodiment, the electrically conductive layer for forming the first electrode 2 includes a portion extending toward the periphery of the light-transmissive substrate 1 so as to overlap the region where the sealing bond 7 is to be formed, and this portion is to be separated from the first electrode 2 and serves as the second electrode extended portion 16. In other words, the electrically conductive layer for forming the second electrode extended portion 16 is on the surface of the light-outcoupling layer 5 close to the covering substrate 6, and extends outside the surface of the light-outcoupling layer 5 so as to be on side surfaces of the light-outcoupling layer 5 (faces facing the sealing bond 7) and the surface of the substrate 1 close to the covering substrate 6. The second electrode extended portion 16 electrically connected to the second electrode 4 is extended to at least a border, between the substrate 1 and the sealing bond 7, of the region (sealed region) enclosed by the substrate 1, the sealing bond 7, and the covering substrate 6. By doing so, the electrode terminal can be formed outside the sealed region. In short, when the second electrode extended portion 16 is formed outside the sealed region, the second electrode extended portion 16 can function as the electrode terminal. In the present embodiment, the second electrode extended portion 16 is extended to the outside of the sealed region. The second electrode extended portion 16 is in contact with the second electrode 4 in the sealed region, and therefore is electrically contact with the second electrode 4.

The first electrode 2, the first electrode extended portion 15, and the second electrode extended portion 16 may be made of the same electrically conductive material. For example, the first electrode 2, the first electrode extended portion 15, and the second electrode extended portion 16 may be made of transparent metal oxide. Specifically, the electrically conductive layer serving as a basis of the first electrode 2, the first electrode extended portion 15, and the second electrode extended portion 16 may be made of ITO. The first electrode 2, the first electrode extended portion 15, and the second electrode extended portion 16 may be made of the above-described material for the light-transmissive electrode (e.g., the electrically conductive oxide such as ITO, IZO, AZO, GZO, and SnO₂, the electrically conductive material such as a metallic nanowire, a metallic thin film, a carbon-based compound, an electrically conductive polymer, and the like, and the combination thereof). In the present embodiment, the first electrode 2, the first electrode extended portion 15, and the second electrode extended portion 16 are transparent electrically conductive layers, which are light-transmissive, transparent, and electrically conductive.

Alternatively, the first electrode extended portion 15 and the second electrode extended portion 16 may be made of electrically conductive materials other than the electrically conductive material for the first electrode 2. In this case, it is possible to form the first electrode extended portion 15 and the second electrode extended portion 16 both having lower electrical resistance than the electrical resistance of the electrically conductive layer for forming the first electrode 2. Since the first electrode extended portion 15 and the second electrode extended portion 16 preferably have low resistance, they may be formed of a metal layer of aluminum, copper, or molybdenum. Furthermore, the first electrode extended portion 15 and the second electrode extended portion 16 may be made of the material for the second electrode 4. Besides, in a case where the first electrode extended portion 15 and the second electrode extended portion 16 are made of a material different from a material of the first electrode 2, the first electrode extended portion 15 and the second electrode extended portion 16 need not be transparent because the first electrode extended portion 15 and the second electrode extended portion 16 are formed on the peripheral region of the substrate 1. Note that both of the first electrode extended portion 15 and the second electrode extended portion 16 may be made of a material other than that for the electrically conductive layer serving as the first electrode 2. Alternatively, either one of the first electrode extended portion 15 and the second electrode extended portion 16 may be made of a material other than that for the electrically conductive layer serving as the first electrode 2.

The covering substrate 6 is bonded to the light-transmissive substrate 1 with the sealing bond 7. The sealing bond 7 surrounds the periphery of the light-emitting stack 10 and is on the surface of the light-transmissive substrate 1. The light-emitting stack 10 is enclosed by bonding the covering substrate 6 and the substrate 1 with the sealing bond 7 which surrounds the periphery of the light-emitting stack 10, and therefore the light-emitting stack 10 is isolated from the outer space of the sealed region.

In the present embodiment, the sealing bond 7 is composed of a multilayer including a bonding layer 9 and the low moisture permeable layer 8, which is lower in moisture permeability and thicker than the bonding layer 9. That is, the sealing bond 7 includes the bonding layer 9 and the low moisture permeable layer 8. The low moisture permeable layer 8 is lower in moisture permeability than the bonding layer 9 and has a thickness (a dimension in the up and down direction in FIG. 1B) greater than the bonding layer 9.

The bonding layer 9 is made of an appropriate bonding material, and may be formed of an adhesive for sealing. For example, the bonding layer 9 may be made of a resinous bonding material. Alternatively, as described below, the bonding layer 9 may be a sealing insulator 13 or an insulating base layer 18. In this case, the bonding layer 9 is made of a material which is electrically insulating and has bonding or adhesive properties. The material for the bonding layer 9 (e.g., the resinous bonding material) preferably has moisture-proof properties. The moisture-proof properties are improved by adding a desiccant, for example. The resinous bonding material may be an adhesive material, or a material containing a heat-curable resin or an ultraviolet-curable resin as a main component.

The light-emitting stack 10 is interposed between the light-transmissive substrate 1 and the covering substrate 6 facing each other and a gap between outer peripheries thereof is closed, and thus the light-emitting stack 10 is enclosed and is isolated from the outside. That is, the light-emitting stack 10 is in the sealed region isolated from the outside. Incidentally, heretofore, in a case of enclosing the organic EL element by bonding the two opposite substrates, the two substrates are bonded with a bond. That is, in the conventional organic EL element, to bond the light-transmissive substrate 1 and the covering substrate 6, the bonding layer 9 made of an adhesive is formed at the periphery of the light-emitting stack 10 so as to be entirely interposed between the light-transmissive substrate 1 and the covering substrate 6 in a thickness direction. That is, in the conventional organic EL element, the thickness of the bonding layer 9 is equal to a distance (a length of a space between the light-transmissive substrate 1 and the covering substrate 6 in the up and down direction in FIG. 1B) between the light-transmissive substrate 1 and the covering substrate 6 which face each other.

In a case where the light-emitting stack 10 does not include the light-outcoupling layer 5, if a moisture-proof resin is used to bond the two substrates, there is possibility of successfully suppressing moisture penetration to an ignorable degree. However, in the organic EL element including the light-emitting stack 10 which is to be sealed and includes the light-outcoupling layer 5 to improve the light-outcoupling efficiency, the thickness of the organic EL element is increased by the thickness of the light-outcoupling layer 5. Therefore, the distance between the light-transmissive substrate 1 and the covering substrate 6 is increased, and as a result the thickness of the bonding layer 9 is increased. In this case, a problem of moisture intrusion into the sealed region through a sealing portion (the bonding layer 9) may arise. In particular, when the light-outcoupling layer 5 is a plastic layer, the light-outcoupling efficiency is improved but the thickness of the light-outcoupling layer 5 is likely to increase. This may causes an increase in thickness of the bonding layer 9, and thus the problem of moisture intrusion through the bonding layer 9 may be more serious. In this case, even when the bonding layer 9 is made of a moisture-proof resin, an increase in the thickness of the bonding layer 9 may cause a considerable moisture intrusion through this bonding layer 9.

In view of this, in the organic EL element of the present embodiment, the light-transmissive substrate 1 and the covering substrate 6 are bonded with the sealing bond 7. The sealing bond 7 is not composed of the bonding layer 9 alone, but is a multilayer of the low moisture permeable layer 8 and the bonding layer 9. Since the sealing bond 7 includes the low moisture permeable layer 8, overall moisture permeability of the sealing bond 7 is lower than the sealing bond 7 composed of the bonding layer 9 alone. Since the light-transmissive substrate 1 and the covering substrate 6 are bonded with such a sealing bond 7 with low moisture permeability, it is possible to more suppress moisture intrusion through the periphery of the sealed region.

Besides, even in a case where the organic EL element does not include the light-outcoupling layer 5, provision of the sealing bond 7 including the low moisture permeable layer 8 enables efficient inhibition of moisture intrusion into the organic EL element by way of the sealing bond 7.

As described above, the organic EL element of the present embodiment includes the following first feature. In the first feature, the organic EL element includes a substrate 1 having the face in the thickness direction of the substrate L the light-emitting stack 10 on the face of the substrate 1; the covering substrate 6 provided so as to face the face of the substrate 1; and the sealing bond 7 surrounding the light-emitting stack 10 and bonding the substrate 1 and the covering substrate 6 to enclose the light-emitting stack 10 together with the covering substrate 6 and the substrate 1. The light-emitting stack 10 includes: the first electrode 2 on the face of the substrate 1; the second electrode 4 provided so as to face the opposite face of the first electrode 2 from the substrate L and the organic layer 3 provided between the first electrode 2 and the second electrode 4 and configured to emit light when a voltage is applied between the first electrode 2 and the second electrode 4. The sealing bond 7 includes the bonding layer 9 and the low moisture permeable layer 8, and the low moisture permeable layer 8 is lower in moisture permeability and thicker than the bonding layer 9.

In the present embodiment, the bonding layers 9 and the low moisture permeable layer 8 are arranged in the thickness direction (up and down direction in FIG. 1B). Therefore, the low moisture permeable layer 8 can be bonded to the substrate 1 and the covering substrate 6 with the bonding layer 9. Generally, decreasing a width (a length in left and right direction in FIG. 1B) of the sealing bond 7 may increase possibility of moisture intrusion into the organic EL element because a path through which moisture needs to pass is shortened. However, in the present embodiment, since the sealing bond 7 includes the bonding layer 9 and the low moisture permeable layer 8 which are arranged in the thickness direction, it is possible to suppress moisture intrusion into the organic EL element and nevertheless easily decrease the width (left and right direction in FIG. 1B) of the sealing bond 7. That is, it is possible to suppress deterioration of the organic layer 3 and yet increase an area for forming the light-emitting stack 10, and thus increase light-emitting region of the organic EL element.

In short, the organic EL element of the present embodiment includes the following second feature in addition to the first feature. In the second feature, the bonding layer 9 and the low moisture permeable layer 8 are arranged in the thickness direction. The second feature is optional.

Besides, the organic EL element of the present embodiment includes the following third feature in addition to the first or second feature. In the third feature, the substrate 1 and the first electrode 2 transmit the light emitted from the organic layer 3. The third feature is optional.

Besides, the organic EL element of the present embodiment includes the following fourth feature in addition to the third feature. In the fourth feature, the light-emitting stack 10 further includes the light-outcoupling layer 5, and the light-outcoupling layer 5 is disposed between the first electrode 2 and the substrate 1 to suppress reflection of the light emitted from the organic layer 3 between the substrate 1 and the light-emitting stack 10. The fourth feature is optional.

In other words, according to the first, third, and fourth features, the organic EL element includes the light-emitting stack 10 on the surface of the light-transmissive substrate 1. In the light-emitting stack 10, the light-outcoupling layer 5, the first electrode 2, the organic layer 3, and the second electrode 4 are arranged in this order. The sealing bond 7 surrounds the periphery of the light-emitting stack 10 and bonds the substrate 1 and the covering substrate 6 to enclose the light-emitting stack 10 together with the covering substrate 6 and the substrate 1. The sealing bond 7 is a multilayer of the bonding layer 9 and the low moisture permeable layer 8, which is lower in moisture permeability and thicker than the bonding layer 9.

Therefore, in the present embodiment, it is possible to improve the light-outcoupling efficiency owing to the light-outcoupling layer 5 and effectively suppress moisture penetration owing to the sealing bond 7 including the low moisture permeable layer 8. Therefore, it is possible to obtain an organic electroluminescence element which has superior light-outcoupling efficiency and yet can suppress moisture intrusion efficiently and thus is highly reliable and is less likely to deteriorate.

In a preferable mode of the organic EL element, the low moisture permeable layer 8 is a metal-containing layer 8a. The metal-containing layer 8a is defined as a layer containing metal. When the low moisture permeable layer 8 contains metal, it is possible to facilitate formation of the layer having lower moisture permeability than the bonding layer 9 and having a great thickness to suppress moisture penetration. When the metal-containing layer 8a serves as the low moisture permeable layer 8, the metal-containing layer 8a is preferably electrically connected to at least one of the first electrode 2 and the second electrode 4. Besides, it is preferable that the metal-containing layer 8a is separated into parts by the sealing insulator 13 in a plan view, and one of the parts of the metal-containing layer 8a serves as a first auxiliary electrode 11 and the other serves as a second auxiliary electrode 12.

In summary, the low moisture permeable layer 8 in the present embodiment is the metal-containing layer 8a containing metal. In the present embodiment, the low moisture permeable layer 8 (metal-containing layer 8a) includes the first auxiliary electrode 11 and the second auxiliary electrode 12 electrically connected to the first electrode 2 and the second electrode 4, respectively. The sealing bond 7 includes the sealing insulator 13 with electrical insulating properties, and the sealing insulator 13 is interposed between the first auxiliary electrode 11 and the second auxiliary electrode 12 to prevent physical contact between the first auxiliary electrode 11 and the second auxiliary electrode 12. Accordingly, electrical insulation between the first auxiliary electrode 11 and the second auxiliary electrode 12 can be further ensured. In the embodiment shown in FIGS. 1A and 1B, the low moisture permeable layer 8 is the metal-containing layer 8a, and the low moisture permeable layer 8 is separated in a plan view so that the first auxiliary electrode 11 and the second auxiliary electrode 12 can serve as the auxiliary electrodes individually to improve electrical conductivity of the first electrode 2 and electrical conductivity of the second electrode 4. The embodiment shown in FIGS. 1A and 1B will be further described.

In the embodiment shown in FIGS. 1A and 1B, the sealing bond 7 is a multilayer including a second bonding layer 9b, the metal-containing layer 8a, and a first bonding layer 9a which are arranged in this order from the light-transmissive substrate 1. That is, the bonding layer 9 is composed of two bonding layers, namely, the first bonding layer 9a and the second bonding layer 9b. The first bonding layer 9a bonds the low moisture permeable layer 8 (metal-containing layer 8a) and the covering substrate 6. The second bonding layer 9b bonds the low moisture permeable layer 8 (metal-containing layer 8a) and the light-transmissive substrate 1.

As described above, the organic EL element of the present embodiment includes the following tenth feature. In this regard, the fifth to ninth features will be described below. In the tenth feature, the bonding layer 9 includes: the first bonding layer 9a bonding the low moisture permeable layer 8 to the covering substrate 6; and the second bonding layer 9b bonding the low moisture permeable layer 8 to the substrate 1. The tenth feature is optional.

The metal-containing layer 8a (low moisture permeable layer 8) has a thickness (a dimension in the up and down direction in FIG. 1B) greater than the total thickness of the two bonding layers 9a and 9b. The metal-containing layer 8a is a layer which contains metal and is lower in moisture permeability than bonding layer 9. Accordingly, it is possible to highly suppress moisture intrusion compared with the case using the sealing bond 7 composed of the bonding layer 9 alone. The metal-containing layer 8a may be made of a metal-containing material which contains metal. The metal containing material may contain a binder so long as the metal containing material contains metal as a main component, but it is preferable that the metal containing material does not contain resin or other organic substances to highly suppress moisture intrusion. For example, the metal-containing layer 8a is a layer (metal layer) made of metal. The metal may be electrical conductive. That is, the metal-containing layer 8a has electrical conductive properties.

The sealing bond 7 including the metal-containing layer 8a of the embodiment in FIGS. 1A and 1B can be easily formed by use of a metal foil tape, for example. The metal foil tape has a stack of a bonding material with bonding properties and metal foil. The bonding material constituting the metal foil tape may be a resinous adhesive. The metal foil may be appropriate foil such as copper foil, silver foil, and aluminum foil. The metal foil of the metal foil tape serves as the metal-containing layer 8a while the bonding material thereof serves as at least one of the two bonding layers 9 (first bonding layer 9a and second bonding layer 9b). In the embodiment shown in FIGS. 1A and 1B, the second bonding layer 9b is the bonding material of the metal foil tape. The metal foil is thin compared with general metal materials, but is sufficiently thicker than the light-emitting stack 10. Therefore, it is possible to easily enclose the light-emitting stack 10 with the thicker sealing bond 7 including the layer of the metal foil.

As described above, the organic EL element of the present embodiment has the following fifth feature. In the fifth feature, the low moisture permeable layer 8 is a metal-containing layer 8a which contains metal.

In other words, in the fifth feature, the low moisture permeable layer 8 is the metal-containing layer 8a. Note that the fifth feature is optional.

In the present embodiment, it is preferable that the second bonding layer 9b is thin so as to allow electric conduction between the metal-containing layer 8a and the electrode extended portion. Accordingly, it is possible to enable electrical conduction between the metal-containing layer 8a and the electrode extended portion, and improve an auxiliary electrode effect on the electrode extended portions, the first electrode 2, and the second electrode 4 caused by the metal-containing layer 8a. The auxiliary electrode effect is an effect of improving electrical conductivities between the external electrodes 20 and the electrode extended portions, the first electrode 2, and the second electrode 4, and is also an effect of equalizing voltage distributions in the first electrode 2 and the second electrode 4. In short, the auxiliary electrode effect is an effect of improving electrical conductivity of the organic EL element. Besides, the second bonding layer 9b may be electrical conductive. In this case, the auxiliary electrode effect is further improved. Moreover, the metal-containing layer 8a has preferably electric conductivity higher than the electric conductivity of the electrical conductive material for the first electrode 2. Accordingly, it is possible to improve function of helping electrical conduction (auxiliary electrode effect) by the metal-containing layer 8a. Besides, in order to further improve the function of helping electrical conduction, the metal-containing layer 8a preferably has high electrical conductivity than that of the material for the second electrode 4.

In the present embodiment, the sealing bonds 7 are individually formed on the surfaces (surfaces close to the covering substrate 6) of the first electrode extended portion 15 and the second electrode extended portion 16 both extending to the periphery of the light-transmissive substrate 1. In short, the metal-containing layers 8a are individually provided on the surfaces of the first electrode extended portion 15 and the second electrode extended portion 16. When the metal-containing layer 8a is provided, the metal-containing layer 8a can highly help improving electrical conductivities of the first electrode 2, the second electrode 4, the first electrode extended portion 15, and the second electrode extended portion 16. The light-transmissive electrode (first electrode 2) normally has high resistance. This resistance may cause a problem such as variation in light-emission distribution in a light-emitting face. Besides, the electrode extended portions are often made of the material for the electrically conductive layer composing the first electrode 2. In the present embodiment, the first electrode 2 is the transparent electrically conductive layer, and the transparent electrically conductive layer has relatively high electrical resistance. However, the metal-containing layer 8a is formed on the surface (face close to the covering substrate 6) of the transparent electrically conductive layer, and also serves as parts of the first electrode 2 and the electrode extended portion. The overall electrical resistance of the stack of the metal-containing layer 8a and the first electrode 2 (namely, combined resistance of the metal-containing layer 8a and the first electrode 2) is lower than the electrical resistance of the first electrode 2 alone. Besides, the overall electrical resistance of the stack of the metal-containing layer 8a and the electrode extended portion (namely, combined resistance of the metal-containing layer 8a and the electrode extended portion) is lower than the electrical resistance of the first electrode extended portion alone. Therefore, the electrical conductivity may be further improved. Moreover, it is possible to improve the function of helping electrical conductivity of the first electrode 2 by the metal-containing layer 8a, and therefore suppress variation in light-emission distribution. Hence, it is possible to obtain more uniform surface emission.

The metal-containing layer 8a formed on the surface of the first electrode extended portion 15 is electrically connected to the first electrode 2. In other words, the metal-containing layer 8a on the first electrode extended portion 15 serves as the first auxiliary electrode 11 electrically connected to the first electrode 2. Besides, the metal-containing layer 8a formed on the surface of the second electrode extended portion 16 is electrically connected to the second electrode 4. In other words, the metal-containing layer 8a on the second electrode extended portion 16 serves as the second auxiliary electrode 12 electrically connected to the second electrode 4. The auxiliary electrodes (first auxiliary electrode 11 and second auxiliary electrode 12) have a function of helping electrical conductivity. Owing to the auxiliary electrodes, even when light-emission region (a region where the first electrode 2, the organic layer 3, and second electrode 4 are stacked in the thickness direction) is increased, the auxiliary electrodes provided on the periphery of the light-emission face (light-emission region) and having low electrical resistance can help electrical conduction, and therefore more uniform emission of the entire light-emission face (light-emission region) can be obtained. Hence, it is possible to produce a large lighting device providing more uniform emission.

As shown in FIG. 1A, the metal-containing layer 8a is separated in a plan view. In other words, the metal-containing layer 8a includes the first auxiliary electrode 11 electrically connected to the first electrode 2 and the second auxiliary electrode 12 electrically connected to the second electrode 4. The first auxiliary electrode 11 and the second auxiliary electrode 12 are not in physical contact with each other. A region interposed between the parts of the metal-containing layer 8a (namely, a region between the first auxiliary electrode 11 and the second auxiliary electrode 12) is situated to overlie a region between the first electrode extended portion 15 and the second electrode extended portion 16. In other words, the first electrode extended portion 15 is not in contact with the second electrode 4 and the second electrode extended portion 16. The second electrode extended portion 16 is not in contact with the first electrode 2 and the first electrode extended portion 15. Accordingly, the first electrode extended portion 15 and the second electrode extended portion 16 are electrically insulated from each other not to cause short-circuiting. On the region interposed between the parts of the metal-containing layer 8a, the sealing insulator 13 is provided. In other words, the sealing insulator 13 is provided between the first auxiliary electrode 11 and the second auxiliary electrode 12 to prevent physical contact between the first auxiliary electrode 11 and the second auxiliary electrode 12. The sealing insulator 13 is provided for enclosing and for ensuring electrical insulation between the first auxiliary electrode 11 and the second auxiliary electrode 12. The sealing insulator 13 constitutes parts of the sealing bond 7 in a plan view. In other words, the sealing bond 7 of the present embodiment includes the sealing insulator 13. The sealing insulator 13 is on the surface of the electrically conductive layer, which constitutes an electrode extended portion, and extends on and between the edges of the first electrode extended portion 15 and the second electrode extended portion 16. The sealing insulator 13 has an end which is in close contact with a side of the metal-containing layer 8a. The first auxiliary electrode 11 and the second auxiliary electrode 12 are required to be electrically insulated from each other, and this electrical insulation is ensured by the sealing insulator 13 interposed between the first auxiliary electrode 11 and the second auxiliary electrode 12. In summary, owing to the sealing insulator 13, it is possible to ensure the electrical insulation between the first electrode extended portion 15 and the second electrode extended portion 16, and enclose and isolate the light-emitting stack 10 from the outside.

The sealing insulator 13 is made of a material having electrically insulating properties. In other words, the sealing insulator 13 has electrically insulating properties. The sealing insulator 13 may be made of a material having moisture-proof properties. The sealing insulator 13 may be provided by disposing a solid member, solidifying a liquid material, or stacking moisture-proof materials. The sealing insulator 13 may be made of a glass material, a moisture-proof resin, an inorganic material, or the like. When the sealing insulator 13 is made of the solid member, the sealing insulator 13 may be bonded with a bonding material. In bonding, it is preferable that the sealing bond 7 does not include any void. Alternatively, when the sealing insulator 13 is made of the liquid material, the sealing insulator 13 is formed by pouring the liquid material into a gap between the metal-containing layers 8a (namely, the region between the first auxiliary electrode 11 and the second auxiliary electrode 12) and then solidifying it. Alternatively, when the sealing insulator 13 is made of the inorganic material, the sealing insulator 13 is constituted by one or more layers of inorganic material in the gap between the metal-containing layers 8a and 8a. Alternatively, the sealing insulator 13 may be formed of the tape with electrical insulating properties.

The bonding layer 9 may or may not overlap a region of sealing bond 7 corresponding to the sealing insulator 13. When the bonding layer 9 does not overlap the above region, the sealing insulator 13 bonds the covering substrate 6 to the low moisture permeable layer 8 and bonds the light-transmissive substrate 1 to the low moisture permeable layer 8. Alternatively, in the region, a bonding layer 9 that is either the first bonding layer 9a or the second bonding layer 9b may be provided. The sealing insulator 13 may be made of the material for the bonding layer 9 (first bonding layer 9a). In this case, it is possible to form, of the same material, the sealing insulator 13 provided between the metal-containing layers 8a and 8a (between the first auxiliary electrode 11 and the second auxiliary electrode 12) and the bonding layer 9 (first bonding layer 9a) to bond the covering substrate 6. Hence, formation of the element can be facilitated. In this case, in the region between the first electrode extended portion 15 and the second electrode extended portion 16, the sealing bond 7 only includes the sealing insulator 13 and does not include the metal-containing layer 8a. However, most of the periphery is enclosed by the metal-containing layer 8a, and therefore high effect of suppressing moisture intrusion is obtained. In short, the sealing insulator 13 may also serve as the bonding layer 9.

The first auxiliary electrode 11 is electrically connected to the first electrode 2. Therefore, the first auxiliary electrode 11 is preferably connected to at least one of the first electrode 2 and the first electrode extended portion 15. In this case, the first auxiliary electrode 11 may be in contact with at least one of the first electrode 2 and the first electrode extended portion 15 at any part. When the metal-containing layer 8a is in contact with at least one of the first electrode 2 and the first electrode extended portion 15 without using the bonding layer 9, it is possible to further improve the electrical conductivity.

The second auxiliary electrode 12 is electrically connected to the second electrode 4. Therefore, the second auxiliary electrode 12 is preferably in contact with at least one of the second electrode 4 and the second electrode extended portion 16. In this case, the second auxiliary electrode 12 may be in contact with at least one of the second electrode 4 and the second electrode extended portion 16 at any part. When the metal-containing layer 8a is in contact with at least one of the second electrode 4 and the second electrode extended portion 16 without using the bonding layer 9, it is possible to further improve the electrical conductivity.

As described above, the organic EL element of the present embodiment has the following seventh feature in addition to the fifth feature. Note that the sixth feature will be described later. In the seventh feature, the metal-containing layer 8a is separated into parts in a plan view, and the separated parts of the metal-containing layer 8a serve as the first auxiliary electrode 11 electrically connected to the first electrode 2 and the second auxiliary electrode 12 electrically connected to the second electrode 4, respectively.

In other words, according to the seventh feature, the low moisture permeable layer 8 (metal-containing layer 8a) further includes the first auxiliary electrode 11 electrically connected to the first electrode 2 and the second auxiliary electrode 12 electrically connected to the second electrode 4, and the sealing bond 7 further includes the sealing insulator 13 having electrically insulating properties and is provided between the first auxiliary electrode 11 and the second auxiliary electrode 12 so that the first auxiliary electrode 11 and the second auxiliary electrode 12 do not physically contact with each other. The seventh feature is optional.

FIGS. 1A and 1B show a preferable example of contact of the auxiliary electrodes with the first electrode 2, the second electrode 4, and electrode extended portions. As the contact of the auxiliary electrodes, the contact in the embodiment shown in FIGS. 1A and 1B will be described below. However, the contact of the auxiliary electrodes is not limited to this.

In the embodiment shown in FIGS. 1A and 1B, a side of the first auxiliary electrode 11 directed to the inside (a side in the sealed region) is in contact with an extended portion of the first electrode 2 on the surface of the light-outcoupling layer 5. That is, the first auxiliary electrode 11 is in contact with the electrically conductive layer serving as the first electrode 2 at an edge of the surface of the light-outcoupling layer 5. Besides, the first auxiliary electrode 11 is in contact with the electrically conductive layer (the first electrode extended portion 15) also serving as the first electrode 2, the electrically conductive layer at a side of the light-outcoupling layer 5. When the electrically conductive layer serving as the first electrode 2 extends across an edge of the light-outcoupling layer 5, at the edge of the light-outcoupling layer 5, breakage caused by edges of steps and thus the electrically conductive layer may be divided unfortunately. This may cause a drop in the electrical conductivity. However, in the present embodiment, the first auxiliary electrode 11 is in contact with the first electrode 2 on the edge of the surface of the light-outcoupling layer 5, namely, the first auxiliary electrode 11 (metal-containing layer 8a) can be in direct contact with the first electrode 2. Therefore, if the electrically conductive layer to serve as the first electrode extended portion 15 is unfortunately divided in a region between the light-outcoupling layer 5 and the light-transmissive substrate 1, the metal-containing layer 8a composing the first auxiliary electrode 11 can be in direct contact with the first electrode 2. Therefore, it is possible to ensure the electrical conductivity and improve electrical reliability. In summary, in the embodiment shown in FIGS. 1A and 1B, the first auxiliary electrode 11 is in direct contact with the first electrode 2 at the side of the first auxiliary electrode 11 close to the sealed region.

Besides, in the embodiment shown in FIGS. 1A and 1B, a side of the second auxiliary electrode 12 directed to the inside (a side in the sealed region) is in contact with the second electrode extended portion 16. That is, the second auxiliary electrode 12 is in contact with the electrically conductive layer serving as the second electrode extended portion 16 at an edge of the surface of the light-outcoupling layer 5. When the electrically conductive layer serving as the first electrode 2 extends across an edge of the light-outcoupling layer 5, at the edge of the light-outcoupling layer 5, breakage caused by edges of steps and thus the electrically conductive layer may be divided, unfortunately. This may cause a drop in the electrical conductivity. However, in the present embodiment, the second auxiliary electrode 12 (metal-containing layer 8a) can be in direct contact with the second electrode extended portion 16 on the side and the surface of the light-outcoupling layer 5. Therefore, if the electrically conductive layer is unfortunately divided in a region between the light-outcoupling layer 5 and the light-transmissive substrate 1, the metal-containing layer 8a composing the second auxiliary electrode 12 can be in direct contact with the second electrode extended portion 16 on the surface and sides of the light-outcoupling layer 5. Therefore, it is possible to ensure the electrical conductivity and improve electrical reliability.

Besides, in the embodiment shown in FIGS. 1A and 1B, a side of the second auxiliary electrode 12 directed to the inside (a side in the sealed region) is in contact with an extended portion of the second electrode 4. In short, the second auxiliary electrode 12 is in contact with the second electrode 4 on the edge of the surface of the light-outcoupling layer 5. In the present embodiment, since the second auxiliary electrode 12 is in contact with the second electrode 4 on the edge of the surface of the light-outcoupling layer 5, the second auxiliary electrode 12 (metal-containing layer 8a) can be in direct contact with the second electrode 4. Therefore, the metal-containing layer 8a composing the first auxiliary electrode 11 is in direct contact with the second electrode 4, and thus it is possible to improve electrical conductivity therebetween and electrical reliability. Besides, when the second electrode 4 is the electrically conductive layer having high electrical conductivity and low electrical resistance, since the second electrode 4 and the second auxiliary electrode 12 are in contact with each other, direct electrical connection may be made between the second electrode 4 and the second auxiliary electrode 12 without using the electrically conductive layer composing the second electrode extended portion 16 and having higher electrical resistance. Accordingly, it is possible to further improve electrical conductivity therebetween. In summary, in the embodiment shown in FIGS. 1A and 1B, the side of the second auxiliary electrode 12 close to the sealed region is in direct contact with the second electrode 4.

In the organic EL element in the present embodiment, the metal-containing layer 8a preferably includes a portion to be connected to the external electrode 20. In this case, the external electrode 20 is connected to the organic EL element through the metal-containing layer 8a. Wires 21 of the external electrodes 20 are required to be connected to the organic EL element for application of a voltage. In the embodiment of FIGS. 1A and 1B, since the first electrode extended portion 15 and the second electrode extended portion 16 extend to the outside of the sealed region, the external electrodes 20 can be connected to the electrode extended portions. However, since the electrode extended portions are composed of transparent electrically conductive layers or the like, in some cases it is difficult to bond the electrode extended portions composed of such a material to the wires 21 of the external electrodes with high adhesion. Besides, there may be a restriction of a bonding material or a formation method. However, when the metal-containing layer 8a composing the auxiliary electrode is connected to the external electrode 20, sufficient connection with the metal-containing layer 8a can be obtained because the metal-containing layer 8a contains metal. Besides, various connection methods such as soldering, wire-bonding, bonding with resin may be adopted. Accordingly, a portion of the metal-containing layer 8a (first auxiliary electrode 11 and second auxiliary electrode 12) is preferably to be connected to the external electrode 20. In other words, the metal-containing layer 8a is preferably electrically connected to the external electrodes for applying a voltage across the light-emitting stack 10. In this case, the metal-containing layer 8a also functions as an extraction electrode. A wire 21A of the external electrode 20 (positive electrode 20A) for the first electrode 2 (anode) is connected to the first auxiliary electrode 11. While, a wire 21B of the external electrode 20 (negative electrode 20B) for the second electrode 4 (cathode) is connected to the second auxiliary electrode 12. The portion to be connected to the external electrode 20 may be a surface or a side of the metal-containing layer 8a. In the present embodiment, the wire 21 electrically connected to the external electrode 20 is connected to an opposite surface (side) of the metal-containing layer 8a from the sealed region.

As described above, the organic EL element of the present embodiment has the following eighth feature in addition to the fifth feature. In the eighth feature, the metal-containing layer 8a has a portion to be connected to the external electrode 20.

In other words, according to the eighth feature, the low moisture permeable layer 8 is formed to electrically connect the light-emitting stack 10 to the external electrode 20 to apply a voltage across the light-emitting stack 10. Note that the eighth feature is optional.

Incidentally, with regard to a ratio in thickness (length in a up and down direction in FIG. 1B) of the low moisture permeable layer 8 (metal-containing layer 8a) to the bonding layer 9, a proportion of the thickness of the low moisture permeable layer 8 to the thickness of the bonding layer 9 may be more than 1 but not more than 100. In this regard, when the bonding layer 9 is composed of a plurality of layers, the thickness of the bonding layer 9 refers to a total thickness of the plurality of layers. In the embodiment shown in FIGS. 1A and 1B, the thickness of the bonding layer 9 is a total thickness of the first bonding layer 9a and the second bonding layer 9b. When the bonding layer 9 is too thick, moisture may be more likely to intrude through the bonding layer 9. Note that, in a case where the low moisture permeable layer 8 is an inorganic insulating layer 8b as described below, similarly to the case where the low moisture permeable layer 8 is the metal-containing layer 8a like in the embodiment shown in FIGS. 1A and 1B, the ratio in thickness of the low moisture permeable layer 8 to the bonding layer 9 is also selected. Besides, the ratio may be selected similarly in a case where the bonding layer 9 is a single layer. Note that the bonding layer 9 has a thickness of about 8 to 10 μm. Note that, when the light-outcoupling layer 5 has a thickness of 10 μm and the element does not include a member such as a desiccant, a gap (a distance between the substrates; a distance between the substrate 1 and the covering substrate 6 in the present embodiment) may be set to about 20 μm. Accordingly, the proportion of the thickness of the low moisture permeable layer 8 to the thickness of the bonding layer 9 is preferably more than the 1. Alternatively, when the element includes the desiccant, the gap is normally selected from about 500 μm to 1 mm. In this case, the proportion of the thickness of the low moisture permeable layer 8 to the thickness of the bonding layer 9 is preferably not more than 100.

In the embodiment in which the sealing bond 7 is composed of the low moisture permeable layer 8 and the bonding layer 9, a proportion of a portion where moisture easily permeates in the sealing bond 7 can be decreased to the proportion of the thickness of the bonding layer 9 to the total of the thicknesses of the bonding layer 9 and the low moisture permeable layer 8. Therefore, even when the width (a length in a left and right direction in FIG. 1B) of the sealing bond 7 is decreased down to be corresponding to the proportion of the thickness of the bonding layer 9 to the total of the thicknesses of the bonding layer 9 and the low moisture permeable layer 8, it is possible to ensure that the present embodiment has the same low-moisture permeability as the general structure devoid of the low moisture permeable layer 8.

The thickness of the sealing bond 7 is preferably not less than the thickness of the light-emitting stack 10. In other words, a total thickness of the bonding layer 9 and the low moisture permeable layer 8 is preferably equal to or more than a total thickness of the light-outcoupling layer 5, the first electrode 2, the organic layer 3, and the second electrode 4. Accordingly, the covering substrate 6 with a plate shape which has a planar face for covering the light-emitting stack 10 (namely, the face of the covering substrate 6 to face the light-transmissive substrate 1) can easily cover the light-emitting stack 10. The sealing bond 7 also serves as a spacer to keep a distance between the substrate 1 and the covering substrate 6 greater than the thickness of the light-emitting stack 10. The covering substrate 6 may have a recessed portion to accommodate the light-emitting stack 10, the recessed portion being formed by scraping or the like. To prepare the element including the recessed portion is troublesome and thus the production cost may increase. In this regard, when the sealing bond 7 has the thickness not less than the thickness of the light-emitting stack 10, namely, the sealing bond 7 is thick, the surface of the sealing bond 7 is positioned higher than the surface of the light-emitting stack 10. That is, the surface of the sealing bond 7 close to the covering substrate 6 is closer to the covering substrate 6 than the surface of the light-emitting stack 10 closer to the covering substrate 6 is. Therefore, the covering substrate 6 can cover the light-emitting stack 10 with its planar face so as not to make a contact of the surface of the covering substrate 6 close to the substrate 1 with the light-emitting stack 10.

Then, described will be the method of preparing the organic EL element of the embodiment shown in FIGS. 1A and 1B.

First, the light-outcoupling layer 5 is formed on the surface of the light-transmissive substrate 1. For example, the light-outcoupling layer 5 may be formed by bonding a plastic sheet to the surface of the light-transmissive substrate 1, which is the glass substrate, by thermocompression bonding. Then, a transparent electrically conductive layer is formed with an appropriate pattern on the surface of the light-transmissive substrate 1 on which the light-outcoupling layer 5 is formed. In this regard, the transparent electrically conductive layer is provided on and extends outside the light-outcoupling layer 5. Besides, the transparent electrically conductive layer has a pattern in which parts of the periphery of the transparent electrically conductive layer are separated from the remaining part of the transparent electrically conductive layer and each serve as the second electrode extended portion 16. The center part of the remaining part of the transparent electrically conductive layer serves as the first electrode 2 and the periphery of the transparent electrically conductive layer connected to the center part serves as the first electrode extended portion 15. The first electrode 2 is formed inside a region of the light-outcoupling layer 5 in a plan view. The formation of the transparent electrically conductive layer may be performed by depositing or applying. Besides, the transparent electrically conductive layer with the pattern may be formed by forming a layer having a desired pattern with a pattern mask or forming a layer on an entire surface and then removing unwanted parts thereof so as to leave the layer with the desired pattern.

Thereafter, the organic layer 3 is formed on the surface of the region, serving as the first electrode 2, of the transparent electrically conductive layer. The organic layer 3 may be formed by stacking layers composing the organic layer 3 sequentially by depositing or applying. After the formation of the organic layer 3, the second electrode 4 is formed on the surface of the organic layer 3. In this regard, the second electrode 4 is formed so as not to be in a contact with the first electrode 2 and the first electrode extended portion 15 but so as to extend to the surface of the second electrode extended portion 16. Accordingly, the light-emitting stack 10 is formed on the surface of the light-transmissive substrate 1.

Subsequently, metal foil tape is attached to a surface of a part, which is extended to the periphery, of the transparent electrically conductive layer, namely, the surface on the opposite side of the first electrode extended portion 15 and the surface on the opposite side of the second electrode extended portion 16, which are formed on the surface of the light-transmissive substrate 1, from the light-transmissive substrate 1. In this regard, the metal foil tape is attached so that the edge of the metal foil tape close to the inside the organic EL element (close to the sealed region) is in close contact with the edge of the light-outcoupling layer 5. Accordingly, the sides of the metal foil tapes can contact with the extended portion of the first electrode 2 and the extended portion of the second electrode 4, respectively. The second bonding layer 9b and the metal-containing layer 8a are formed by attaching the metal foil tape. Note that the metal foil tape does not extend across the region between the edges of the first electrode extended portion 15 and the second electrode extended portion 16. That is, in the region, the metal foil tape is not provided. In other words, pieces of the metal foil tape are attached to the first electrode extended portion 15 and the second electrode extended portion 16, respectively without electrically interconnecting the first electrode extended portion 15 and the second electrode extended portion 16.

On the surface of the metal foil tape (the opposite face of the metal foil from the bonding material), namely, on the surface of the metal-containing layer 8a (the opposite surface of the metal-containing layer 8a from the light-transmissive substrate 1), an adhesive for sealing is provided, and thereafter the covering substrate 6 is bonded to enclose the light-emitting stack 10. The adhesive for sealing is formed into the first bonding layer 9a. In this regard, on the region between the first electrode extended portion 15 and the second electrode extended portion 16, namely, on the region between the metal-containing layer 8a constituting the first auxiliary electrode 11 and the metal-containing layer 8a constituting the second auxiliary electrode 12, the adhesive for sealing is provided. Accordingly, the sealing insulator 13 is made of the adhesive for sealing and can fill the gap between the metal-containing layers 8a (between the first auxiliary electrode 11 and the second auxiliary electrode 12) and thus sealing is made. In this case, the adhesive for sealing is an adhesive with electrical insulating properties. The adhesive for sealing may be an appropriate resin such as a heat-curable resin and an ultraviolet-curable resin. In a case of using the heat-curable resin, the heat curing temperature thereof is selected to be lower than the heatproof temperature of plastic constituting the light-outcoupling layer 5. Note that, the sealing insulator 13 may be formed by disposing another material such as a glass piece between the metal-containing layers 8a and 8a (between the first auxiliary electrode 11 and the second auxiliary electrode 12). Alternatively, the sealing insulator 13 may be formed by disposing an inorganic material as described below.

Accordingly, the organic EL element of the embodiment shown in FIGS. 1A and 1B can be obtained.

Note that, in the above-described method, a step of attaching the metal foil tape to the light-transmissive substrate 1 is performed after the step of preparing the light-emitting stack 10. The method of preparing the organic EL element of the embodiment shown in FIGS. 1A and 1B is not limited to the above manner. For example, the metal foil tape may be attached after the formation of the electrically conductive layer constituting the first electrode 2 and before the formation of the organic layer 3. In this method, the second electrode 4 is formed so as to be in contact with the edge of the metal-containing layer 8a. Accordingly, the second electrode 4 and the metal-containing layer 8a (second auxiliary electrode 12) is in contact with each other, and it is possible to ensure electrical conductivity.

Alternatively, the metal foil tape is attached to the surface of the covering substrate 6 in advance, and the covering substrate 6 to which the metal foil tape is attached may be bonded with the adhesive for sealing to the light-transmissive substrate 1 on which the light-emitting stack 10 is provided. That is, a housing member composed of the covering substrate 6 and the metal foil tape is formed in advance, and then the light-emitting stack 10 is enclosed with this housing member. In this case, the bonding material of the metal foil tape serves as the first bonding layer 9a, and the adhesive for sealing serves as the second bonding layer 9b. In this case, the adhesive for sealing to form the second bonding layer 9b is an adhesive with electrical insulating properties.

Note that, to form the organic EL element in which the light-emitting stack 10 does not include the light-outcoupling layer 5, the electrically conductive layer that is a base for the first electrode 2, the first electrode extended portion 15, and the second electrode extended portion 16 and has an appropriate pattern is formed directly on the face of the substrate 1. After formation of the electrically conductive layer, the organic EL element devoid of the light-outcoupling layer 5 can be formed in a manner similar to the manner for forming the organic EL element of the above embodiment shown in FIG. 1.

Incidentally, for preparation of a plurality of organic EL elements, the plurality of organic EL elements may be formed so as to have a continuous common light-transmissive substrate 1, and then the light-transmissive substrate 1 is cut to give the individual organic EL elements. Accordingly, the plurality of the organic EL elements may be formed simultaneously. In this case, the plurality of the organic EL elements can be formed simultaneously, and therefore it is possible to improve efficiency in preparation. When the plurality of organic EL elements are formed simultaneously, the light-outcoupling layer 5 is attached to the entire surface of the common light-transmissive substrate 1, and then parts of the light-outcoupling layer 5 to be on the periphery of each organic EL element are removed. Accordingly, the light-outcoupling layer 5 is provided on a scheduled region for the light-emitting stack 10. Of course, the light-outcoupling layers 5 may be provided on individual regions for the organic EL elements. Subsequently, similarly to the above-described method, layers are formed, and the light-emitting stack 10 may be enclosed by the covering substrate 6, the substrate 1 and the sealing bond 7. Similarly to the light-transmissive substrate 1, the covering substrate 6 may be a continuous common covering substrate 6. At last, the light-transmissive substrate 1 and the covering substrate 6 are cut along the periphery of each organic EL element, and as a result, the organic EL elements are separated.

### First Modification

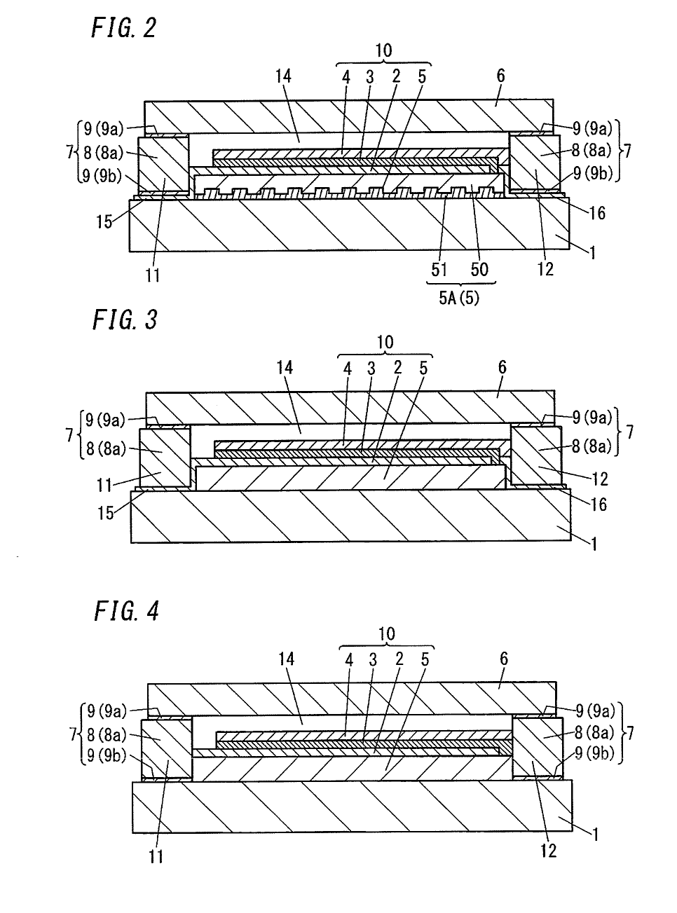

FIG. 2 shows the first modification of the embodiment of the organic EL element. The same components as those in the embodiment (basic example) shown in FIGS. 1A and 1B are attached with the same reference signs, and therefore description thereof will be omitted. Note that, in FIG. 2, the external electrodes 20 and the wires 21 are not illustrated, however, the organic EL element of the first modification has the eighth feature. Therefore, the light-emitting stack 10 is electrically connected to the external electrodes 20 through the low moisture permeable layers 8.

The first modification is different from the embodiment shown in FIGS. 1A and 1B only in the structure of the light-outcoupling layer 5. The light-outcoupling layer 5(5A) of the first modification has a function of scattering light. Since the light-outcoupling layer 5A has a function of scattering light, light proceeding towards the light-transmissive substrate 1 is scattered by the light-outcoupling layer 5A, and thus total reflection is suppressed. Accordingly, light can be extracted more.

For example, the light-outcoupling layer 5A has a diffraction structure to diffract light. The light-outcoupling layer 5A has the diffraction structure, and therefore can scatter light. The diffraction structure may be an appropriate uneven structure. The uneven structure may be a structure where fine protrusions are arranged in a plane, for example. Each protrusion may have an appropriate shape such as a hemispherical shape, a wrinkled shape, a pyramidal shape (quadrangular pyramidal shape), and a frustum shape. The protrusions may be arranged in a regular pattern or in an irregular pattern.

In the first modification, the light-outcoupling layer 5A is formed by stacking a plurality (two, in the figure) of layers 50 and 51 in the thickness direction of the substrate 1, and has a diffraction structure at an interface between the plurality of layers 50 and 51. Note that, the light-outcoupling layer 5A may have a diffraction structure on its surface, for example, a surface of the light-outcoupling layer 5 close to the substrate 1.

Note that the refractive index of the light-outcoupling layer 5A having the function of scattering light may be in a range between refractive indices of the first electrode 2 and the light-transmissive substrate 1. Accordingly, it is possible to efficiently suppress the total reflection, between the light-emitting stack 10 and the light-transmissive substrate 1, of light emitted from the organic layer 3.

Whether the light-outcoupling layer 5 has the function of scattering light may be optionally selected. That is, in each of the organic EL elements of the second to sixth modifications as described below, the light-outcoupling layer 5 may be replaced by the light-outcoupling layer 5A in a similar manner to the first modification.

As described above, in the organic EL element of the first modification, the light-outcoupling layer 5 has the diffraction structure as an in-cell structure. The in-cell structure is a particular optical structure (diffraction structure in the first modification), and has a function of improving light-transmitting efficiency of parts between the first electrode 2 and the substrate 1.

### Second Modification

FIG. 3 shows another example (second modification) of the embodiment of the organic EL element. The same components as those in the embodiment shown in FIGS. 1A and 1B are attached with the same reference signs, and therefore description thereof will be omitted. Note that, in FIG. 3, the external electrodes 20 and the wires 21 are not illustrated, however, the organic EL element of the second modification has the eighth feature.

The modification shown in FIG. 3 is different from the embodiment shown in FIGS. 1A and 1B in the sealing bond 7 which is composed of the low moisture permeable layer 8 (metal-containing layer 8a) and a single bonding layer (first bonding layer 9a). Other configurations are similar to those shown in FIGS. 1A and 1B.

In the second modification, the low moisture permeable layer 8 (metal-containing layer 8a) of the sealing bond 7 is formed by disposing a metal containing material on the electrode extended portion. In this case, the second bonding layer 9b in the embodiment shown in FIGS. 1A and 1B is not required. When the second bonding layer 9b is not formed, the metal-containing layer 8a and the electrode extended portion are in direct contact with each other without a bonding material. Therefore, electrical conduction between the metal-containing layer 8a and the electrode extended portion can be further improved.

The modification shown in FIG. 3 can be prepared by, after formation of the first electrode 2 or the second electrode 4, forming the metal-containing layer 8a by applying or depositing a metal-containing material on the first electrode extended portion 15 and the second electrode extended portion 16. Alternatively, in the modification shown in FIG. 3, the metal-containing layer 8a is formed on the covering substrate 6 to give the housing member in advance, and the light-emitting stack 10 may be enclosed by the housing member and the substrate 1.

As described above, the organic EL element of the second modification has the eleventh feature in addition to any one of the first to ninth features. In the eleventh feature, the low moisture permeable layer 8 is formed on one of the substrate 1 and the covering substrate 6, and the bonding layer 9 bonds the low moisture permeable layer 8 to the other of the substrate 1 and the covering substrate 6. Note that the eleventh feature is optional.

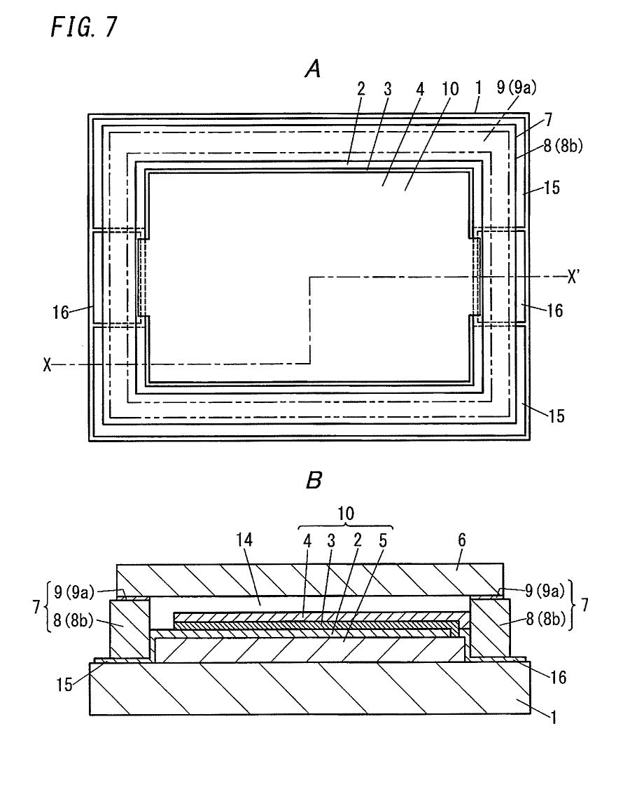

Besides, in the organic EL element having the eleventh feature, the low moisture permeable layer 8 may be the metal-containing layer 8a as with the present embodiment, or the inorganic insulating layer 8b as described below in the modification shown in FIGS. 7A and 7B, for example.

### Third Modification

FIG. 4 shows another example (third modification) of the embodiment of the organic EL element. The same components as those in the embodiment shown in FIGS. 1A and 1B are attached with the same reference signs, and therefore description thereof will be omitted. Note that, in FIG. 4, the external electrodes 20 and the wires 21 are not illustrated, however, the organic EL element of the third modification also has the eighth feature.

In the modification shown in FIG. 4, the electrically conductive layer constituting the first electrode 2 is within a region of the light-outcoupling layer 5 in a plan view. That is, the electrically conductive layer constituting the first electrode 2 is only in the sealed region. In other words, the electrically conductive layer does not extend outside the light-outcoupling layer 5, and the first electrode extended portion 15 and the second electrode extended portion 16 are not formed on the surface of the light-transmissive substrate 1. The sealing bond 7 is composed of the first bonding layer 9a, the low moisture permeable layer 8 (metal-containing layer 8a), and the second bonding layer 9b, as with that in the embodiment of FIGS. 1A and 1B.

In the third modification, the edge of the sealing bond 7 inside the organic EL element is in close contact with the side edge (periphery) of the light-outcoupling layer 5. Then, the edge of the first electrode 2 and the edge of the metal-containing layer 8a (first auxiliary electrode 11) are in contact with each other. The first auxiliary electrode 11 and the second auxiliary electrode 12 are separated from each other by the sealing insulator 13 in a plane view, as with the embodiment shown in FIGS. 1A and 1B. In the third modification, the first auxiliary electrode 11 and the second auxiliary electrode 12 help electrical conduction of the first electrode 2 and the second electrode 4, respectively, and electrically connect with the external electrodes 20, respectively. The first auxiliary electrode 11 is directly connected to the first electrode 2 while the second auxiliary electrode 12 is directly connected to the second electrode 4, and therefore it is possible to further improve overall electrical conductivity. Besides, in the third modification, since there is no need to form the electrically conductive layer extending across the edge of the light-outcoupling layer 5, it is unnecessary to consider division resulting from discontinuity of the electrically conductive layer which is caused by breakage at edges of steps. The electrically conductive layer for forming the first electrode 2 can be easily formed.

In summary, the third modification shown in FIG. 4 is different from the basic example of the organic EL element in that the electrically conductive layer for forming the first electrode 2 is formed only inside the sealed region and the first electrode extended portion 15 and the second electrode extended portion 16 are not formed. In the above description the third modification included the light-outcoupling layer 5, but the light-outcoupling layer 5 is not provided necessarily.

As with the embodiment shown in FIGS. 1A and 1B, the modification shown in FIG. 4 may be formed by the method including the step of forming the metal-containing layer 8a by attaching the metal foil tape after the formation of the first electrode 2 or the light-emitting stack 10. Alternatively, the modification shown in FIG. 4 may be formed by the method including a step of forming the metal-containing layer 8a by attaching the metal foil tape, after the formation of the light-outcoupling layer 5 and before the formation of the first electrode 2. Alternatively, the metal-containing layer 8a may be formed by attaching the metal foil tape to the light-transmissive substrate 1 before the formation of the light-outcoupling layer 5. In this way, the metal-containing layer 8a can be formed at an appropriate timing, and therefore variation in preparation can be improved.

Note that in the modification of the FIG. 4 as with the modification of the FIG. 3, the metal-containing layer 8a may be not formed of the metal foil tape but may be formed of material containing metal. In this case, the second bonding layer 9b or first bonding layer 9a may not be provided.

### Fourth Modification

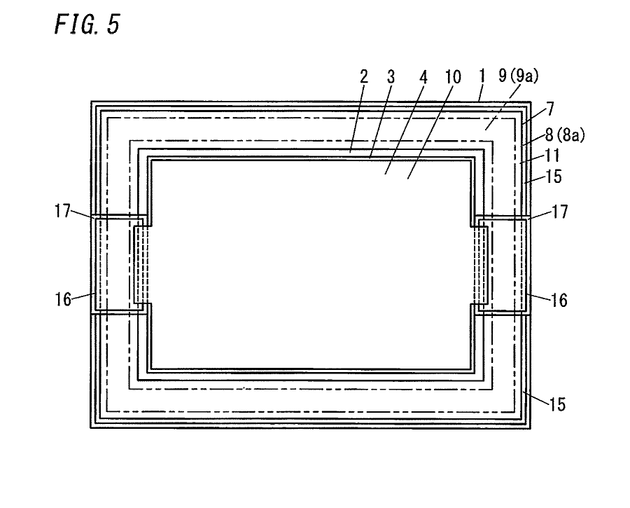

FIG. 5 shows another example (fourth modification) of the embodiment of the organic EL element. The same components as those in the embodiment shown in FIGS. 1A and 1B are attached with the same reference signs, and therefore description thereof will be omitted. Note that, in FIG. 5, as with FIG. 1A, to briefly illustrate the configuration of the organic EL element, the covering substrate 6 is not illustrated, and a region where the first bonding layer 9a is to be formed is indicated by two-dot chain lines. Note that, in FIG. 5, the external electrodes 20 and the wires 21 are not illustrated, however, the organic EL element of the fourth modification also has the eighth feature.

In the modification of FIG. 5, the electrically conductive layer for forming the first electrode 2 is not separated but extends to an entire periphery of the substrate 1 and reaches an edge of the substrate 1. That is, the first electrode extended portion 15 is formed on a periphery of the light-transmissive substrate 1 while the second electrode extended portion 16 is not formed on the surface of the light-transmissive substrate 1. Besides, the metal-containing layer 8a is formed of metal foil tape or the like on the surface of the first electrode extended portion 15 and on a peripheral edge of the surface of the light-transmissive substrate 1.

The metal-containing layer 8a is electrically connected to the first electrode extended portion 15. Therefore, the metal-containing layer 8a is electrically connected to the first electrode 2, and the whole of the metal-containing layer 8a serves as the first auxiliary electrode 11. The metal-containing layer 8a is not electrically connected to the second electrode 4.

As described above, in the fourth modification, the sealing insulator 13 is not provided, and the metal-containing layer 8a is not separated. Therefore, the metal-containing layer 8a serves as the first auxiliary electrode 11 but does not serve as the second auxiliary electrode 12. Alternatively the metal-containing layer 8a may serve as the second auxiliary electrode 12 but may not serve as the first auxiliary electrode 11. That is, in the fourth modification, the metal-containing layer 8a may serve as either one of the first auxiliary electrode 11 and the second auxiliary electrode 12.

On the part of the surface of the metal-containing layer 8a, the insulating extended portion 17 is provided. This insulating extended portion 17 extends from the inside of the sealed region to the outside and partially covers the metal-containing layer 8a and the first electrode extended portion 15 in a plan view. On the opposite surface of the insulating extended portion 17 from the metal-containing layer 8a, the second electrode extended portion 16 is formed. The second electrode 4 is formed on to be in contact with the second electrode extended portion 16.

That is, in the fourth modification, the insulating extended portion 17 is provided between the first electrode extended portion 15 and the second electrode extended portion 16 so that the second electrode extended portion 16 does not physically contact with the first electrode extended portion 15 and the first auxiliary electrode 11. Accordingly, it is possible to electrically insulate the first auxiliary electrode 11 from the second electrode 4 and the second electrode extended portion 16. Besides, it is possible to electrically insulate the first electrode extended portion 15 from the second electrode 4 and the second electrode extended portion 16.

For example, when the second electrode extended portion 16 in contact with the second electrode 4 is extended to a region between the first auxiliary electrode 11 (metal-containing layer 8a) and the covering substrate 6, the insulating extended portion 17 is formed so as to cover the side close to the sealed region of the first auxiliary electrode 11 and the surface close to the covering substrate 6 of the first auxiliary electrode 11 as well as the surface of the first electrode extended portion 15 close to the covering substrate 6. In the fourth modification, the second electrode extended portion 16 is not required to be transparent.

In the modification of FIG. 5, the metal-containing layer 8a is electrically connected to only the first electrode 2 and is formed on the entire periphery of the light-transmissive substrate 1. Therefore, a region where the metal-containing layer 8a covers the first electrode extended portion 15 is increased, and thus an area of the first auxiliary electrode 11 is increased. Hence, the metal-containing layer 8a can assist in improving electrical conductivity of the electrically conductive layer composing the first electrode 2. Besides, the metal-containing layer 8a with low-moisture permeability extends along the periphery of the light-transmissive substrate 1. Hence, it is possible to highly suppress water penetration. Note that the insulating extended portion 17 has electrically insulating properties, and is present between the second electrode extended portion 16 and a set of the first electrode extended portion 15 and the metal-containing layer 8a. That is, electrical insulation between the first electrode extended portion 15 and the second electrode extended portion 16 is kept by the insulating extended portion 17. Hence, short-circuiting is prevented successfully.

In the modification of FIG. 5, on parts of the surface of the metal-containing layer 8a, the insulating extended portion 17 and the second electrode extended portion 16 are formed. However, when the thickness of the bonding layer 9 (first bonding layer 9a) is greater than the total of the thicknesses of the insulating extended portion 17 and the second electrode extended portion 16, the covering substrate 6 can be bonded to the metal-containing layer 8a. Alternatively, the metal-containing layer 8a partially has a recess, and the sealing bond 7 and the second electrode extended portion 16 may be formed in the recess.

In the fourth modification, when the second electrode extended portion 16 is provided between the first auxiliary electrode 11(metal-containing layer 8a) and the covering substrate 6, the first bonding layer 9a may be made of a material having electrical insulating properties so as to electrically insulate the second electrode extended portion 16 and the first auxiliary electrode 11.

As described above, the fourth modification of the organic EL element has the following sixth feature in addition to the fifth feature. In the sixth feature, the low moisture permeable layer 8 is electrically connected to either the first electrode 2 or the second electrode 4. Note that the sixth feature is optional.

Additionally, a combination of the sixth and seventh features can be interpreted as that the metal-containing layer 8a is electrically connected to either the first electrode 2 or the second electrode 4.

### Fifth Modification

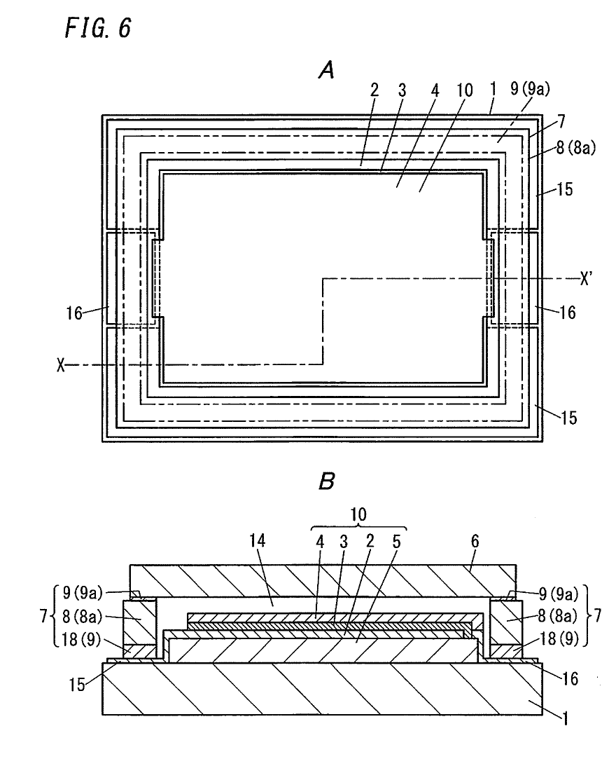

FIGS. 6A and 6B show another example (fifth modification) of the embodiment of the organic EL element. The same components as those in the embodiment shown in FIGS. 1A and 1B are attached with the same reference signs, and therefore description thereof will be omitted. Note that, in FIG. 6A as with FIG. 1A, to briefly illustrate the configuration of the organic EL element, the covering substrate 6 is not illustrated, and a region where the first bonding layer 9a is to be formed is indicated by two-dot chain lines.

In the modification shown in FIGS. 6A and 6B, the sealing bond 7 is composed of an insulating base layer 18, a metal-containing layer 8a, and a bonding layer (first bonding layer 9a). That is, the sealing bond 7 further includes the insulating base layer 18. The insulating base layer 18 has electrically insulating properties, and insulates the metal-containing layer 8a from the first electrode extended portion 15 and the second electrode extended portion 16. The insulating base layer 18 may serve as a foundation for the metal-containing layer 8a. The metal-containing layer 8a is electrically insulated from both of the first electrode extended portion 15 and the second electrode extended portion 16 by the insulating base layer 18 which is closer to the light-transmissive substrate 1 than the metal-containing layer 8a. That is, the insulating base layers 18 are provided between the metal-containing layer 8a and the first electrode extended portion 15 and between the metal-containing layer 8a and the second electrode extended portion 16, respectively. Therefore, the metal-containing layer 8a does not have a function as an auxiliary electrode. The metal-containing layer 8a serves as the housing member and the spacer material.

The insulating base layer 18 may be made of, for example, a material for the bonding layer 9 so long as the insulating base layer 18 has electrically insulating properties. The first bonding layer 9a composing the insulating base layer 18 is thickened so long as the total thickness of the bonding layer 9 is smaller than the metal-containing layer 8a. The insulating properties of the insulating base layer 18 are increased with an increase in the thickness of the insulating base layer 18. Alternatively, the insulating base layer 18 may be made of an inorganic material described below. In this case, the insulating base layer 18 serves as the bonding layer 9. The total thickness of the insulating base layer 18 and the bonding layer 9 is selected smaller than the low moisture permeable layer 8.

In FIGS. 6A and 6B, the low moisture permeable layer 8 is constituted by the metal-containing layer 8a and does not include the insulating base layer 18. However, the insulating base layer 18 may be a part of the low moisture permeable layer 8. That is, the insulating base layer 18 may have lower moisture-permeability than the bonding layer 9. For example, when the insulating base layer 18 is a layer composed of the inorganic material described below as a main component, the insulating base layer 18 has a lower moisture-permeability than the bonding layer 9, and thus the insulating base layer 18 becomes a part of the low moisture permeable layer 8.

In the fifth modification, the light-emitting stack 10 is surrounded by the metal-containing layer 8a which has low-moisture permeability. Therefore, it is possible to improve an effect of suppressing moisture intrusion.

The modification shown in FIGS. 6A and 6B may be prepared by forming the insulating base layers 18 and the metal-containing layers 8a in this order on the individual surfaces of the first electrode extended portion 15 and the second electrode extended portion 16. The insulating base layer 18 may be formed by depositing or applying an inorganic material or a resinous material. The metal-containing layer 8a may be formed by attaching the metal foil tape or disposing the metal-containing material. When the insulating base layer 18 is made of the resinous material, it is preferable to use a resinous material with moisture-proof properties. To ensure the insulating properties, the width (a length in a left and right direction in FIG. 6A) of the metal-containing layer 8a may be smaller than the width of the insulating base layer 18.

The external electrodes 20 may be connected to the first electrode extended portion 15 and the second electrode extended portion 16, respectively. Alternatively, the electrode extended portions may be extended further to the outside to form auxiliary electrodes of electrically conductive material, and the external electrodes 20 may be connected to the auxiliary electrodes.

### Sixth Modification

FIGS. 7A and 7B show another example (sixth modification) of the embodiment of the organic EL element. The same components as those in the embodiment shown in FIGS. 1A and 1B are attached with the same reference signs, and therefore description thereof will be omitted. Note that, in FIG. 7A, as with FIG. 1A, to briefly illustrate the configuration of the organic EL element, the covering substrate 6 is not illustrated, and a region where the first bonding layer 9a is to be formed is indicated by two-dot chain lines.

In the modification shown in FIGS. 7A and 7B, the low moisture permeable layer 8 is an inorganic insulating layer 8b containing an inorganic component as a main component. In other words, the low moisture permeable layer 8 is the inorganic insulating layer 8b which is made of an inorganic material and has electrically insulating properties. The inorganic insulating layer 8b is provided along an entire periphery of the light-emitting stack 10. Therefore, the periphery of the sealed region is surrounded by the low moisture permeable layer 8 which is the inorganic insulating layer 8b. Accordingly, the sealed region is enclosed by surrounding the periphery of the sealed region with the inorganic insulating layer 8b with low moisture permeability, and thus it is possible to highly suppress moisture intrusion into the sealed region. Besides, owing to the inorganic insulating layer 8b, it is possible to easily thicken the sealing bond 7 and enclose the light-emitting stack 10.

The inorganic insulating layer 8b containing an inorganic component as a main component may contain an organic component or resin for a binder as a subcomponent. However, the inorganic insulating layer 8b preferably does not contain the organic component and resin. Accordingly, it is possible to enhance the effect of suppressing moisture penetration. The inorganic component composing the inorganic material may include at least one type selected from general inorganic insulating filler such as SiO₂, SiN(SiNx), SiC, and AlN. Using these materials may lead to improvement on barrier performance to water. Alternatively, it is preferable that the inorganic material is glass, and the metal-containing layer 8a is composed of a glass particle-containing composition or applied glass. In the glass particle-containing composition, glass particles are dispersed in a fluid medium. The applied glass is a fluid glass material. Solidifying the fluid glass material or glass composition leads to formation of the inorganic insulating layer 8b. When the inorganic insulating layer 8b is made of glass, the thick inorganic insulating layer 8b with low-moisture permeability can be easily obtained.

The modification shown in FIGS. 7A and 7B may be prepared by forming the electrically conductive layer composing the first electrode 2 and then forming the inorganic insulating layer 8b (low moisture permeable layer 8) by deposing or applying the inorganic material on the surfaces of the first electrode extended portion 15 and the second electrode extended portion 16. The inorganic insulating layer 8b may be formed after the formation of the light-emitting stack 10. The inorganic insulating layer 8b may extend over an entire periphery of the surface of the substrate 1 close to the substrate 1. In this regard, the inorganic insulating layer 8b may be formed on a region between the first electrode extended portion 15 and the second electrode extended portion 16. When the gap between the electrode extended portions (between the first electrode extended portion 15 and the second electrode extended portion 16) is filled with the inorganic insulating layer 8b, it is possible to enhance sealing properties and suppress moisture intrusion. Then, the bonding material for sealing is provided on the surface of the inorganic insulating layer 8b close to the covering substrate 6, and the covering substrate 6 is bonded. Consequently, the light-emitting stack 10 is enclosed, and the bonding layer 9 (first bonding layer 9a) is formed between the inorganic insulating layer 8b and the covering substrate 6. The bonding material for sealing may be the same as that used in the embodiment shown in FIGS. 1A and 1B, namely, the adhesive for sealing.

The external electrodes 20 may be connected to the first electrode extended portion 15 and the second electrode extended portion 16, respectively. Alternatively, the electrode extended portions may be extended further to the outside to form auxiliary electrodes of electrically conductive material, and the external electrodes 20 may be connected to the auxiliary electrodes.

Note that, the inorganic insulating layer 8b is formed on the surface of the covering substrate 6 to give a housing member in advance, and the light-emitting stack 10 may be covered with the housing member. In this case, the bonding layer 9 (second bonding layer 9b) is formed between the inorganic insulating layer 8b and the light-transmissive substrate 1.

In summary, in the sixth modification, as with the modification of FIG. 3, the low moisture permeable layer 8 is formed on one of the light-transmissive substrate 1 and the covering substrate 6, and the bonding layer 9 bonds the low moisture permeable layer 8 to the other of the light-transmissive substrate 1 and the covering substrate 6. Note that, the configuration in which the sealing bond 7 includes the inorganic insulating layer 8b as the low moisture permeable layer 8 may be applied to not only a mode in which either one of the first bonding layer 9a or the second bonding layer 9b is provided as the bonding layer 9 but also a mode in which both the first bonding layer 9a and the second bonding layer 9b are provided as the bonding layer 9.

As described above, the sixth modification of the organic EL element has the ninth feature in addition to any one of the first to fourth features. In the ninth feature, the low moisture permeable layer 8 is the inorganic insulating layer 8b containing the inorganic component as a main component.

In other words, in the ninth feature, the low moisture permeable layer 8 is the inorganic insulating layer 8b made of the inorganic material and having electrically insulating properties. Note that the ninth feature is optional.

As describe above, the organic EL element of the embodiment of the present invention includes the light-outcoupling layer 5. Therefore, it is possible to improve light-outcoupling efficiency. Besides, in the organic EL element, the sealing bond 7 includes the low moisture permeable layer 8. Therefore, moisture is less likely to intrude into the inside of the organic EL element, and thus it is possible to suppress deterioration of the organic EL element. Consequently, it is possible to obtain the organic EL element with excellent light-outcoupling efficiency and high reliability.

1. An organic electroluminescence element comprising:
a substrate having a face in a thickness direction of the substrate;
a light-emitting stack on the face of the substrate;
a covering substrate provided so as to face the face of the substrate; and
a sealing bond surrounding the light-emitting stack and bonding the substrate and the covering substrate to enclose the light-emitting stack together with the covering substrate and the substrate,
the light-emitting stack including:
a first electrode on the face of the substrate;
a second electrode provided so as to face an opposite face of the first electrode from the substrate; and
an organic layer provided between the first electrode and the second electrode and configured to emit light when a voltage is applied between the first electrode and the second electrode,
the sealing bond including a bonding layer and a low moisture permeable layer, and
the low moisture permeable layer being lower in moisture permeability and thicker than the bonding layer.

2. The organic electroluminescence element according to claim 1, wherein
the bonding layer and the low moisture permeable layer are arranged in the thickness direction.

3. The organic electroluminescence element according to claim 1, wherein
the substrate and the first electrode transmit the light emitted from the organic layer.

4. The organic electroluminescence element according to claim 3, wherein:
the light-emitting stack further includes a light-outcoupling layer; and
the light-outcoupling layer is disposed between the first electrode and the substrate to suppress reflection of the light emitted from the organic layer between the substrate and the light-emitting stack.

5. The organic electroluminescence element according to claim 1, wherein
the low moisture permeable layer is a metal-containing layer which contains metal.

6. The organic electroluminescence element according to claim 5, wherein
the low moisture permeable layer is electrically connected to either the first electrode or the second electrode.

7. The organic electroluminescence element according to claim 5, wherein:
the low moisture permeable layer includes a first auxiliary electrode electrically connected to the first electrode and a second auxiliary electrode electrically connected to the second electrode;
the sealing bond further includes a sealing insulator having electrically insulating properties; and
the sealing insulator is provided between the first auxiliary electrode and the second auxiliary electrode to prevent physical contact between the first auxiliary electrode and the second auxiliary electrode.

8. The organic electroluminescence element according to claim 5, wherein
the low moisture permeable layer is formed to electrically connect the light-emitting stack to external electrodes to apply a voltage across the light-emitting stack.

9. The organic electroluminescence element according to claim 1, wherein
the low moisture permeable layer is an inorganic insulating layer made of an inorganic material and having electrically insulating properties.

10. The organic electroluminescence element according to claim 1, wherein
the bonding layer includes a first bonding layer bonding the low moisture permeable layer to the covering substrate and a second bonding layer bonding the low moisture permeable layer to the substrate.

11. The organic electroluminescence element according to claim 1, wherein:
the low moisture permeable layer is provided on either one of the substrate and the covering substrate; and
the bonding layer bonds the low moisture permeable layer to the other of the substrate and the covering substrate.
